(19) United States
(12) Patent Application Publication
(10) Pub. No.: US 2025/0370334 A1
(43) Pub. Date: Dec. 4, 2025

(54) COMPLEX, INORGANIC PHOTORESIST COMPOSITION COMPRISING THE SAME, AND MANUFACTURING METHOD OF SEMICONDUCTOR DEVICE USING THE SAME

(71) Applicant: Samsung Electronics Co., Ltd., Suwon-si (KR)

(72) Inventors: Hoyoung KIM, Suwon-si (KR); HyeongJun KIM, Suwon-si (KR); Jinjoo KIM, Suwon-si (KR); Younghun SHIN, Suwon-si (KR); Kunyoung LEE, Suwon-si (KR)

(73) Assignees: Samsung Electronics Co., Ltd., Suwon-si (KR); Sogang University Research & Business Development Foundation, Seoul (KR)

(21) Appl. No.: 19/001,873

(22) Filed: Dec. 26, 2024

(30) Foreign Application Priority Data
Jun. 3, 2024 (KR) 10-2024-0072324

(51) Int. Cl. G03F 7/004; C08F 20/38; G03F 7/00; G03F 7/038; G03F 7/039; G03F 7/20; H01L 21/033

(52) U.S. Cl. CPC G03F 7/0043; C08F 20/38; G03F 7/0388; G03F 7/039; G03F 7/2004; G03F 7/70033; H01L 21/0332

(57) ABSTRACT

Provided are an inorganic photoresist composition and a method of manufacturing a semiconductor device using the same, the inorganic photoresist composition includes a cage-type tin oxide cluster having a cation and a polymer having an acidic functional group, wherein the acidic functional group forms electrostatic attractive force with the cage-type tin oxide cluster. By using the complex, photoresist stability is secured through electrostatic attractive force between the cluster and polymer, thereby enhancing pattern stability after exposure and development.

### CROSS-REFERENCE TO RELATED APPLICATION

This application claims priority to and the benefit of Korean Patent Application No. 10-2024-0072324 filed in the Korean Intellectual Property Office on Jun. 3, 2024, the entire contents of which are incorporated herein by reference.

### BACKGROUND OF THE INVENTION

### (a) Field of the Invention

This disclosure relates to an organic-inorganic complex based on an electrostatic attractive force between a cationic tin oxide cluster and a polymer having an acidic functional group, an inorganic photoresist composition including the complex, and a method of manufacturing a semiconductor device using the same.

### (b) Description of the Related Art

Extreme ultraviolet light (EUV) technology, which uses light of about 13.5 nm, may be applied to realize resolutions of pitch line width of less than or equal to about 40 nm. The extreme ultraviolet light (EUV) technology using extreme ultraviolet light (EUV) with a very short wavelength, of which photons have high energy of about 92 eV but low density, may deteriorate pattern performance due to the unique stochastic effect. In order to improve the pattern performance deterioration, research and development of a tin-based inorganic photoresist using a tin oxide nano compounds with high absorption of EUV wavelengths is being conducted.

However, the tin oxide nano compound exhibits high resolution for fine line widths based on the high absorbance for EUV but has poor structural stability due to strong propensity for crystallinity between particles and thereby easy structural deformation, which bring about problems of causing precipitation in a solution and deteriorating process stability and film uniformity.

In order to solve the problems, the present inventors have synthesized an ionic functional group (functional group) configured to improve stability through an electrostatic attractive force with tin oxide nanocage and proposed a photoresist process of forming a complex including the organic polymer.

### SUMMARY OF THE INVENTION

One aspect of the present disclosure provides an organic metal complex that can improve the long-term storage stability of an inorganic photoresist composition and improve uniformity during thin film coating, specifically a complex based on electrostatic attractive force between a tin oxide cluster having cations and a polymer having an acidic functional group, furthermore, an inorganic photoresist composition including the above complex and a method of manufacturing a semiconductor device including a patterning process using the same.

A complex according to one aspect includes a tin oxide cluster including cations; and a polymer including an acidic functional group forming an electrostatic attractive force with the tin oxide cluster.

The tin oxide cluster may have a cage type.

The acidic functional group may include at least one of an anionic functional group or a Lewis acid functional group at a terminal end.

The anionic functional group may include at least one of a sulfurous acid (SO3−), a carbonate (CO3−), a nitric acid (NO3−), a functional group represented by Chemical Formula 1, a functional group represented by Chemical Formula 2, or a combination thereof.

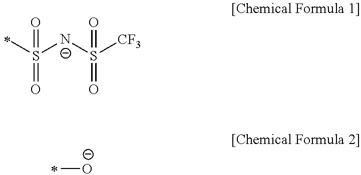

The Lewis acid functional group may include boronic acid.

The polymer may further include an additional functional group different from the acidic functional group.

The additional functional group may include at least one of a first additional functional group, a second additional functional group, or a third additional functional group.

The first additional functional group may include a functional group derived from an acrylic monomer.

The acrylic monomer may be a sulfur-free monomer that does not carry an electric charge.

The second additional functional group may include a functional group derived from a monomer represented by Chemical Formula 3.

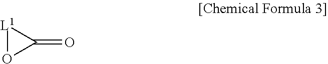

In Chemical Formula 3,
L¹ is a substituted or unsubstituted C1 to C20 alkylene group.

L1 may be a substituted or unsubstituted C3 alkylene group.

The third additional functional group may include a functional group derived from a monomer including at least one of a halogen atom or an aromatic monomer.

The at least one monomer selected from the monomer including the halogen at least one of atom or aromatic monomer may be included in an amount of about 5 wt % to about 10 wt % based on a total amount of monomers constituting the polymer.

The polymer may have a number of average molecular weight of less than or equal to about 10,000 g/mol.

The tin oxide cluster and the polymer in the complex may have a molar ratio of about 50:1.

An inorganic photoresist composition according to one aspect includes the complex; and a solvent.

The inorganic photoresist composition may be a composition for extreme ultraviolet (EUV) light.

A method of manufacturing a semiconductor device according to one aspect includes coating the inorganic photoresist composition on a substrate; drying the composition to obtain a film; exposing the film to light; and developing the film after exposure.

The exposing of the film may include exposing the film to extreme ultraviolet (EUV) light.

Since the complex according to one aspect is based on electrostatic attractive force between the tin oxide cluster and organic ion polymer, it can not only improve the long-term storage stability of the photoresist composition, but also improve thin film uniformity and thermal stability when applying the photoresist composition to a thin film and improve photoresist pattern stability, and resistance to etching solutions can also be improved in the etching process performed after pattern formation.

### BRIEF DESCRIPTION OF THE DRAWINGS

FIG. 1 shows the structure of a complex according to one aspect, and is a diagram schematically showing the structure of a complex in which cage-type tin oxide nanoclusters and a polymer having an acidic functional group are bonded by electrostatic attractive force.

FIG. 2 shows the structure of a polymer in a complex according to one aspect, showing that the polymer may include an acidic functional group and three additional functional groups different from this. A is an acidic functional group, B is a compatible functional group as the first additional functional group, C is a soluble functional group as the second additional functional group, and D is a functional group as the fourth additional functional group.

FIGS. 3 and 4 show the long-term storage stability of particles (complexes or tin oxide nanoclusters) in the photoresist composition, and FIG. 3 is a graph showing the transmittance over time of each photoresist composition in Example 1 and Comparative Example 1 and a photograph showing the composition on the 7th day, and FIG. 4 is a graph showing the change in size of the particles over time.

FIG. 5 is an SEM photograph of a film coated with the photoresist composition of Comparative Example 1 on a silicon wafer.

FIG. 6 is an SEM photograph of a thin film coated with the photoresist composition of Example 1 on a silicon wafer.

FIGS. 7 and 8 are x-ray diffraction (XRD) graphs showing the crystallinity of thin films coated with the photoresist compositions of Example 1 and Comparative Example 1, respectively.

### DETAILED DESCRIPTION OF THE EMBODIMENTS

Hereinafter, various embodiments of the present disclosure will be described in detail with reference to the accompanying drawings so that those of ordinary skill in the art may easily implement the present disclosure. The present disclosure may be implemented in various different forms and is not limited to the embodiments described herein.

The drawings and description are to be regarded as illustrative in nature and not restrictive. Like reference numerals designate like elements throughout the specification, and therefore repeat descriptions thereof may be omitted.

The size and thickness of each constituent element as shown in the drawings may be exaggerated for better understanding and ease of description, and this disclosure is not necessarily limited to as shown. For example, in the drawings, the thickness of layers, films, panels, regions, etc., may be exaggerated for clarity. In addition, in the drawings, for better understanding and ease of description, the thickness of some layers and areas may be exaggerated. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

In addition, throughout the specification, when referring to “plane”, it means when the target part is viewed from above, and when referring to “cross section”, it means when viewing the cross section of the target portion vertically cut from the side.

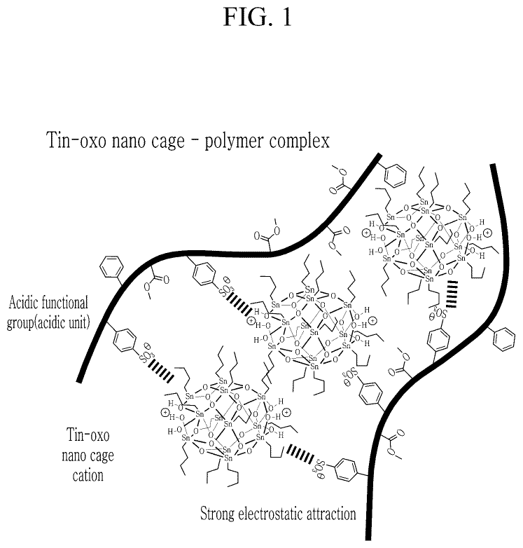

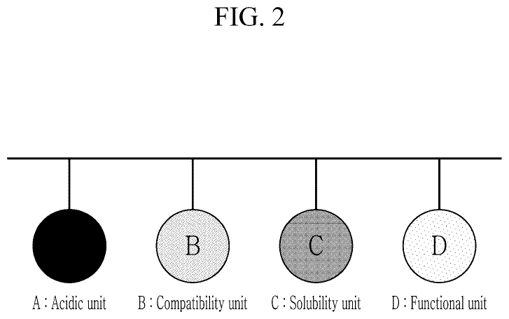

The present disclosure relates to an organic metal compound in an inorganic photoresist composition used in a patterning process during a semiconductor process and specifically, a complex between cation of a tin oxide cluster and an organic polymer including an ionic functional group configured to form a strong ionic bond with the cation of the tin oxide cluster. Through this organic metal compound, photoresist stability may be secured, and in particular, the composition may be very appropriate to use for an EUV photoresist patterning process. In other words, the present disclosure is intended to solve the problem of insufficient stability of tin oxide cage-based EUV photoresist compositions, by providing an ionic polymer, as shown in FIG. 2, and a complex between “ionic polymer and cage-type tin oxide cluster,” as shown in FIG. 1. The ionic polymer itself is not used as an EUV photoresist composition. In other words, an inorganic photoresist composition according to one aspect is prepared by additionally adding the ionic polymer to the cage-type tin oxide cluster-based EUV photoresist composition. If the ionic polymer is added to the cage-type tin oxide cluster-based EUV photoresist composition, the complex between “ionic polymer—cage-type tin oxide cluster” is formed by a strong electrostatic attractive force, and the complex may be distributed in the form of particles in the EUV photoresist compositions.

Conventionally, inorganic photoresist compositions composed of an organic metal-based chalcogen compound had been introduced but, in that particles within the inorganic photoresist compositions have a very small (e.g., nanometer scale) and uniform size, had a problem of deteriorated solubility and structural stability due to strong attraction and crystallization between the particles. The present inventors have invented the complex, which is introduced into an inorganic photoresist composition to secure long-term stability between particles within the inorganic photoresist composition even in a solvent.

Without being limited to a specific theory, the stability improvement is a result of the strong electrostatic attractive force between cations of the tin oxide cluster and acidic functional groups in the organic polymer.

For example, the tin oxide cluster may be referred to as being a cage type and/or, a nano-sized cage type. In other words, the tin oxide cluster may be a tin oxide nanocage type. For example, the tin oxide cluster may have a cage-like structure.

In at least some examples, the acidic functional group may include an anionic functional group or a Lewis acid functional group at the terminal end. The anionic functional group or Lewis acid functional group at the terminal end of the acidic functional group may form a strong electrostatic interaction with the cations of the tin oxide cluster, forming a complex.

For example, the anionic functional group may include at least one of sulfurous acid (SO3−), carbonate (CO3−), nitric acid (NO3−), a functional group represented by Chemical Formula 1, a functional group represented by Chemical Formula 2, or a combination thereof, and the Lewis acid functional group may include boronic acid. The anionic functional group or the Lewis acid functional group is not necessarily limited thereto, and may include other anionic functional groups selected based on solubility in the semiconductor, stability, reactivity, and the. The Lewis acid functional group may not be anionic like the anionic functional group but provide electrons to stabilize the tin oxide cluster, which may have a similar effect to the electrostatic interaction.

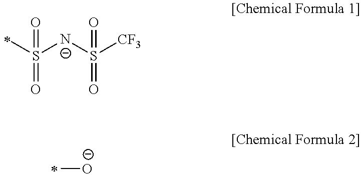

In at least some examples, the anionic functional group, before the electrostatic interaction with cations of the tin oxide cluster, may take the form of a salt by interacting with imidazole cations. For example, in order to synthesize a polymer having the acidic functional group, a monomer (ionic liquid monomer) having an acidic functional group may be first synthesized, wherein the acidic functional group may include an anionic functional group (and/or the like) at the terminal end, and the anionic functional group at the terminal end may be in the form of a salt as shown below.

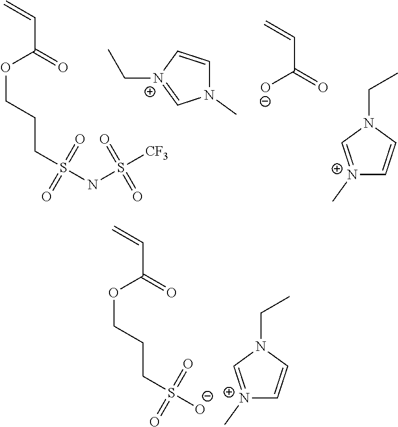

The ionic liquid monomer may have imidazole cations and thus may be introduced into the semiconductor process in which metal cations are limitedly used. And, because the ionic liquid monomer is an acrylate-based ionic liquid, a polymer may be easily synthesized through a free radical chain-growth polymerization (FRP) reaction.

For example, after synthesizing the ionic liquid monomer, an ionic liquid polymer may be obtained through a FPR reaction such as Reaction Scheme 1.

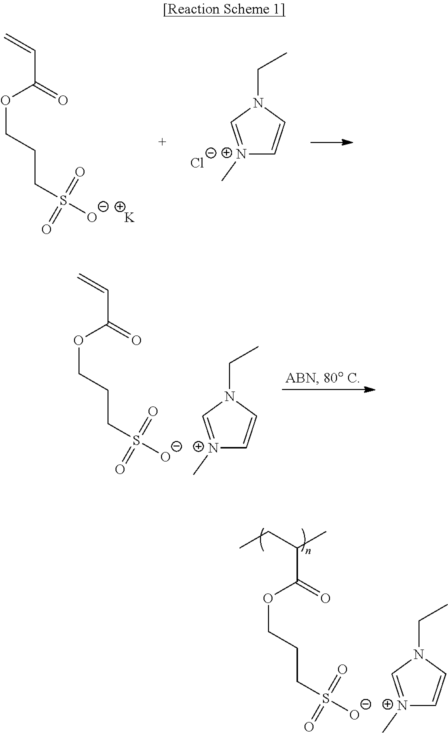

In at least some examples, the polymer may be a homogenous polymer or a random and/or block copolymer. For example, the polymer may further include additional functional groups different from the acidic functional groups.

For example, the additional functional group may include at least one selected from a first additional functional group, a second additional functional group, and/or a third additional functional group. As shown in FIG. 2, the acidic functional group may be represented as A, and as shown above, plays a role of forming a strong electrostatic interaction with cations of the tin oxide cluster. The acidic functional group may be a functional group derived from a monomer including the anionic functional group and/or the Lewis acid functional group, wherein the monomer may be an acrylic monomer but derived from other types of monomers rather than the acrylic monomer.

On the other hand, the first additional functional group may be represented by B, as shown in FIG. 2, and serve as a compatibility functional group (e.g., serve to improve stability of the complex). For example, the first additional functional group may include a functional group derived from an acrylic monomer, wherein the acrylic monomer may be a sulfur-free monomer that does not carry an electric charge. If the acrylic monomer is not charged, the acrylic monomer may not form a strong electrostatic attractive force with cations of the tin oxide cluster, and if sulfur atoms are included therein, the sulfur atoms may interfere the electrostatic interaction between the anionic functional group and the cation of the tin oxide cluster, which may be undesirable. For example, the acrylic monomer may be an acrylic monomer substituted or unsubstituted with an uncharged (linear or branched) alkyl group. If the acrylic monomer is an acrylic monomer substituted with a substituent other than the alkyl group (for example, an acrylic monomer substituted with a cycloalkyl group) the monomer may have too large a size to easily synthesize an ionic liquid polymer through a free radical polymerization reaction, and even if the polymer is synthesized, the electrostatic attractive force may be weak.

The second additional functional group may be represented as C in FIG. 2 and serve as a dissolution functional group (e.g., serve to improve solubility) so that the complex may be well distributed in the photoresist composition. For example, the second additional functional group may be derived from a monomer known to have high solubility in a general photoresist solvent. For example, in at least some examples, the second additional functional group may include a functional group derived from a monomer represented by Chemical Formula 3 but is not necessarily limited thereto.

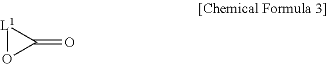

In Chemical Formula 3,
L¹ is a substituted or unsubstituted C1 to C20 alkylene group.

For example, L1 may be a substituted or unsubstituted C3 alkylene group.

For example, the second additional functional group may include a functional group derived from gamma butyrolactone.

The third additional functional group may be represented by D in FIG. 2, is an enhancer functional group (e.g., contribute to EUV absorbance and/or plays a role in improving the overall performance of the photoresist by playing a role in increasing the life time of secondary electrons generated by EUV). Accordingly, the third additional functional group may include a functional group derived from at least one monomer selected from a monomer including a halogen atom and an aromatic monomer with high EUV absorbance. The halogen atom may be fluorine or iodine. However, if the content of at least one monomer selected from the monomer including the halogen atom and the aromatic monomer is excessive, there may be side effects in film stability and solubility of the complex, and thus at least one monomer selected from the monomer including the halogen atom and the aromatic monomer may be included in an amount of 5 wt % to 10 wt % based on a total amount of monomers constituting the polymer.

For example, when the types of monomers constituting the polymer are A, B, C, and D in FIG. 2, if only the monomer content of D is controlled as above, even if the contents of the remaining monomers (A, B, and C) are controlled, no additional positive or negative effects may appear. In other words, even if only the monomer content of D is controlled as above, the content of the remaining monomers (A, B, and C) can be freely adjusted to specifically improve performance.

On the other hand, if the synthesized polymer has a low glass transition temperature, it exists in liquid form at room temperature. The ionic liquid monomer used in Reaction Scheme 1 is 3-sulfopropyl acrylate monomer, and the polymer obtained by free radical polymerization has a low glass transition temperature of −5° C., so that it exists as a liquid (or gel) at room temperature.

When using liquid (or gel) polymers in the coating process, there is a problem in which the polymers tend to gradually clump together after coating. Therefore, ionic polymers that exist in solid form rather than liquid (or gel) form at room temperature may be used in the coating process to reduce and/or prevent clumping. For example, a polymer synthesized by copolymerizing polystyrene (PS) and/or polymethyl methacrylate (PMMA with the 3-sulfopropyl acrylate monomer (See Reaction Scheme 2 and Reaction Scheme 3) may be used to reduce and/or prevent clumping. Furthermore, by changing the acrylate-based anionic monomer to methacrylate-based (e.g., changing 3-sulfopropyl acrylate monomer to 3-sulfopropyl methacrylate monomer), the glass transition temperature is increased to proceed polymer synthesis in solid form at room temperature.

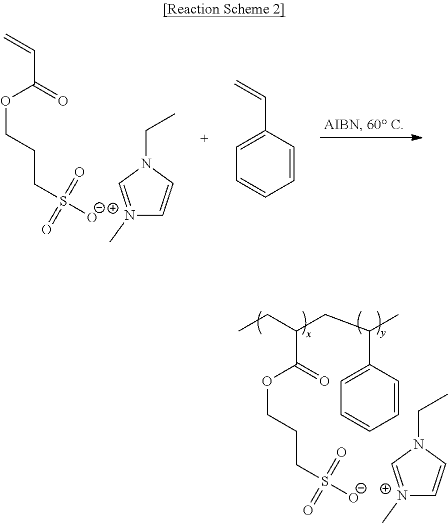

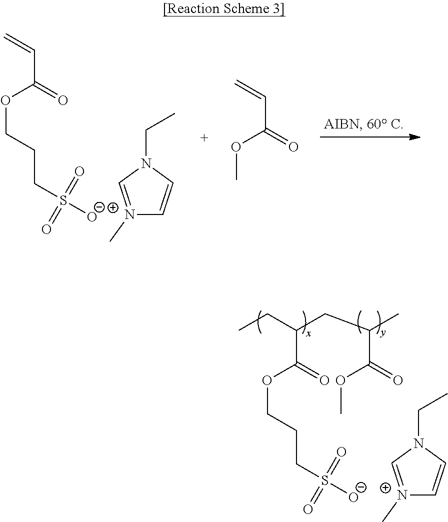

Meanwhile, the number average molecular weight of the polymer may be less than or equal to about 10,000 g/mol in order to improve in terms defect performance.

For example, the tin oxide cluster and the polymer in the complex may have a molar ratio of about 100:1 to about 50:1, for example, about 50:1. In some examples, the (cage-type) tin oxide cluster and the polymer are placed in an alcohol solvent such as ethanol at a molar ratio of about 50:1 and stirred to proceed with the ion exchange reaction, and then the alcohol is completely evaporated, to obtain a complex having a structure as shown in FIG. 1. When the tin oxide cluster and the polymer have a mixed molar ratio, complex formation can be facilitated.

According to one aspect, an inorganic photoresist composition including the ionic polymer-tin oxide nanocage cluster complex and a solvent is provided. At this time, the inorganic photoresist composition may be a composition for extreme ultraviolet (EUV) light.

For example, the solvent may include an organic solvent, and the organic solvent may include alcohols such as ethanol, isopropanol, and 1-butanol; polyhydric alcohols such as ethylene glycol, diethylene glycol, propylene glycol, and dipropylene glycol; ketones such as acetone, methyl ethyl ketone, cyclohexanone, methyl-n-amyl ketone, methyl isoamyl ketone, and 2-heptanone; esters such as ethyl acetate, propyl acetate, butyl acetate, methyl lactate, ethyl lactate, methyl pyruvate, ethyl pyruvate, methyl methoxypropionate, ethyl methoxypropionate, methyl ethoxypropionate, ethyl ethoxypropionate, propylene glycol monomethyl ether acetate, etc.; an aromatic based organic solvent such as anisole, ethylbenzyl ether, cresylmethyl ether, diphenyl ether, dibenzyl ether, phenetol, butylphenyl ether, ethylbenzene, diethylbenzene, isopropylbenzene, amylbenzene, toluene, xylene, trimethylbenzene, etc.; lactones such as γ-butyrolactone; cyclic ethers such as dioxane; amines such as N,N-dimethylacetamide; halogens such as chloroform and methylene chloride, but the solvent is not necessarily limited thereto. The organic solvent may be used individually, or may be used in combination of two or more types.

The EUV inorganic photoresist composition based on the ionic polymer-tin oxide nanocage cluster complex can contribute to mass production because the ionic polymer-tin oxide nanocage cluster complex has the effect of improving stability in solution and process stability after application to the wafer compared to existing EUV inorganic photoresist compositions. In addition, the performance of the overall photoresist in terms of lithography and defects can be improved due to the effects of monomers (functional groups) that play various roles contained in the ionic polymer. Specifically, as semiconductors become miniaturized, there is a demand for the development of a patterning process that can form ultra-fine patterns narrower than about 32 nm. The inorganic photoresist composition according to one aspect can be applied to the next generation, that is, an ultra-fine patterning process narrower than about 32 nm, to form an ultra-fine pattern. That is, according to the inorganic photoresist composition for EUV according to one aspect, it is possible to form a resist film with excellent film quality (pattern clarity) and substrate adhesion (developer resistance), so that even in thin patterns with the above-mentioned line width, it may be possible to form a good pattern in which the occurrence of defects is suppressed and residual film in unnecessary portions is suppressed.

According to one aspect, provided is a patterning method (resist pattern forming method) that includes coating the inorganic photoresist composition on a substrate; drying the inorganic photoresist composition to obtain a film; exposing the film to light; and performing development after exposure the step of developing after exposure. Additionally, a method of manufacturing a semiconductor device including the patterning method is provided. At this time, the exposing of the film may be exposing the film to extreme ultraviolet (EUV) light.

The step of coating the inorganic photoresist composition on the substrate is not particularly limited but may use any coating method such as Ink jetting, spraying, spin coating, dip coating, roll coating, and the like to form a resist film, but the spin coating may be desirable to form a uniform thin film.

The inorganic photoresist composition is applied, for example, to a substrate, etc., wherein the substrate may have any dimension and any size without particular limitations, but examples of a material thereof may include silicon, SiC, a nitride semiconductor, GaAs, AlGaAs, etc. In addition, the substrate, on which a resist film is formed, may have a thin film processed into a desired pattern by dry etching and/or the like, and the corresponding thin film may include a polysilicon thin film or a laminated film of the polysilicon thin film with a metal thin film, a metal thin film, an insulating thin film such as an Si oxide film, an Si nitride film, an Si oxynitride film, etc., and/or the like. On the thin film, an organic film may also be formed. The inorganic photoresist composition may be used to form an upper resist film in a multi-layered resist structure.

A coating amount of the inorganic photoresist composition may be appropriately controlled, for example, to adjust the resist film to have an appropriate thickness to be described later.

The method for forming a pattern according to one aspect includes a process of drying the film of the inorganic photoresist composition. The process of drying the film of the inorganic photoresist composition may reduce a solvent content in the film of the inorganic photoresist resist composition.

The method of drying the film of the inorganic photoresist composition is not particularly limited. For example, the film may be heated to remove an organic solvent remaining in the resist film. The heating may be performed at greater than or equal to about 70° C., greater than or equal to about 80° C., and/or greater than or equal to about 90° C. and less than or equal to about 300° C., less than or equal to about 250° C., and/or less than or equal to about 200° C. The heating may be performed under two or more different conditions. The heating time may be greater than or equal to about 10 seconds, greater than or equal to about 20 seconds, or greater than or equal to about 30 seconds and less than or equal to about 300 seconds, less than or equal to about 200 seconds, and/or less than or equal to about 150 seconds. Herein, producibility, film quality, or substrate close contacting property of the resist film tend to be improved.

The method of drying the film of the inorganic photoresist composition may be performed under any condition of a reduced pressure, a normal pressure, or a higher pressure and under an inert atmosphere.

The drying is performed so that the solvent in the film after the drying (the resist film after the drying) may be mostly removed. For example, the film after the drying may have a solvent content of less than or equal to about 1000 ppm.

The film of the inorganic photoresist composition may be exposed to EUV to form an exposed portion of the film or cure an unexposed portion of the film.

A method of exposing the film of the inorganic photoresist composition to EUV, according to at least some examples, may include exposing the inorganic photoresist composition through a desired mask pattern using an EUV light source.

An exposure light source used for the exposure may include an exposure light source (LPP) that extracts EUV light from plasma generated by irradiating a target such as tin or a compound thereof, xenon, and the like, an EUV exposure light source (DPP) that extracts EUV light from plasma generated by high-voltage discharge by causing tin, a compound thereof, or xenon around an electrode including tungsten, silicon carbide, or the like, an EUV exposure light source that extract EUV light from plasma generated by additional discharge, or an EUV exposure light source that extracts EUV light from a radiation light source, an electron beam irradiation source, etc. A reflective or transmissive filter may be used to extract EUV from the EUV light sources.

Development of the film (resist film) of the inorganic photoresist composition is optional, but can be performed using water, alkaline water, an organic solvent, or a mixture thereof. Examples of solvents that can be used as a developer include the above organic solvents. Suitable organic solvents may include, for example, alcohols such as 4-methyl-2-pentanol, 1-butanol, isopropanol, 1-propanol, and methanol; esters such as ethyl lactate; ethers such as tetrahydrofuran, dioxane, and anisole; amines such as tetramethylammonium hydroxide; etc.

In at least some examples, the developing solution is optional, but may include a viscosity modifier, solubilization aid, surfactant, etc. depending on the purpose.

A developing time may be greater than or equal to about 10 seconds, greater than or equal to about 20 seconds, and/or greater than or equal to about 30 seconds, and may be less than or equal to about 300 seconds, less than or equal to about 200 seconds, and/or less than or equal to about 100 seconds. When step (iv) is performed within the above range, the productivity of the resist film, the film quality of the resist film, and the adhesion to the substrate tend to improve.

The development method is not particularly limited, and examples include the immersion method, paddle method, and spray method.

The film thickness of the resist film after development may be greater than or equal to about 10 nm, may be greater than or equal to about 20 nm, and/or may be greater than or equal to about 30 nm, and may be less than or equal to about 100 nm, less than or equal to about 80 nm, and/or less than or equal to about 60 nm. In addition, the film thickness may be determined according to a minimum processing dimension of a desired pattern. Within the ranges, film quality of the resist film or dimensional stability of the resist pattern tends to be improved.

The method of forming patterns may further include any step (process) in addition to the above steps (process). The any process may be a process of baking the resist film after the EUV exposure. This process may be performed after the exposure, and the baking may be performed at a temperature of greater than or equal to about 70° C., greater than or equal to about 90° C., and/or greater than or equal to about 110° C. and less than or equal to about 300° C., less than or equal to about 250° C., and/or less than or equal to about 200° C. The heating may be performed under 2 or more different conditions. The heating time may be greater than or equal to about 10 seconds, greater than or equal to about 30 seconds, greater than or equal to about 60 seconds and less than or equal to about 300 seconds, less than or equal to about 150 seconds, or less than or equal to about 120 seconds. Herein, producibility, film quality, or substrate close contacting property of the resist film tends to be improved.

Although the examples embodiments have been described above, the embodiments are not limited to the examples described above, and various additions, omissions, substituted, and changes may be made. Further, it is possible to form other embodiments by combining elements in different embodiments.

Hereinafter, various experiments conducted to evaluate grain size and resistivity using a metal deposition aid according to an embodiment will be described. The experiments described below do not limit the present disclosure.

### EXAMPLES

### Synthesis of Polymer

### Synthesis Example 1

A polymer (number average molecular weight: 6000 g/mol) was synthesized by free radical-polymerizing (using AIBN as an initiator) a 3-sulfopropyl acrylate monomer at 60° C. The synthesized polymer had imidazole cations.

### Synthesis Example 2

A polymer was synthesized by free radical-polymerizing (using AIBN as an initiator) a 3-sulfopropyl acrylate monomer and a polymethylmethacrylate monomer at 60° C. The synthesized polymer had imidazole cations.

### Synthesis Example 3

A polymer was synthesized in the same manner as in Synthesis Example 2 except that a 1-adamantylmethacrylate monomer was used instead of the polymethylmethacrylate monomer.

### Synthesis Example 4

A polymer was synthesized in the same manner as in Synthesis Example 2 except that a monomer derived from gamma-butyrolactone was used instead of the polymethylmethacrylate monomer.

### Synthesis Example 5

A polymer was synthesized by free radical-polymerizing (using AIBN as an initiator) a 3-sulfopropyl acrylate monomer, a polymethylmethacrylate monomer, and a monomer derived from gammabutyrolactone at 60° C. The synthesized polymer had imidazole cations.

### Synthesis Example 6

A polymer was synthesized by free radical-polymerizing (using AIBN as an initiator) a 3-sulfopropyl acrylate monomer, a polymethylmethacrylate monomer, a monomer derived from gamma-butyrolactone, and a styrene monomer at 60° C. Herein, a weight of the styrene monomer was controlled to be 5 wt % based on a total weight of 4 types of the monomers. The synthesized polymer had imidazole cations.

### Synthesis Example 7

A polymer was synthesized in the same manner as in Synthesis Example 6 except that the weight of the styrene monomer was changed to 10 wt % instead of 5 wt %.

### Synthesis Example 8

A polymer was synthesized in the same manner as in Synthesis Example 6 except that the weight of the styrene monomer was changed to 4 wt % instead of 5 wt %.

### Synthesis Example 9

A polymer was synthesized in the same manner as in Synthesis Example 6 except that the weight of the styrene monomer was changed to 12 wt % instead of 5 wt %.

### Synthesis Example 10

A polymer was synthesized in the same manner as in Synthesis Example 1 except that the number average molecular weight was controlled to be 8,000 g/mol instead of 6,000 g/mol.

### Synthesis Example 11

A polymer was synthesized in the same manner as in Synthesis Example 1 except that the number average molecular weight was controlled to be 10,000 g/mol instead of 6,000 g/mol.

### Synthesis Example 12

A polymer was synthesized in the same manner as in Synthesis Example 1 except that the number average molecular weight was controlled to be 11,000 g/mol instead of 6,000 g/mol.

### Comparative Synthesis Example 1

A polymer was synthesized in the same manner as in Synthesis Example 1 except that a polymethylmethacrylate monomer was used instead of the 3-sulfopropyl acrylate monomer.

### Comparative Synthesis Example 2

A polymer was synthesized in the same manner as in Synthesis Example 1 except that a monomer derived from gammabutyrolactone was used instead of the 3-sulfopropyl acrylate monomer.

### Comparative Synthesis Example 3

A polymer was synthesized in the same manner as in Synthesis Example 1 except that a styrene monomer was used instead of the 3-sulfopropyl acrylate monomer.

### Comparative Synthesis Example 4

A polymer was synthesized in the same manner as in Synthesis Example 1 except that an 1-adamantylmethacrylate monomer was used instead of the 3-sulfopropyl acrylate monomer.

### Preparation of Inorganic Photoresist Compositions

### Example 1

The polymer of Synthesis Example 1 was added to an inorganic photoresist composition including a cationic cage-type tin oxide cluster (using PGMEA as a solvent) to prepare an inorganic photoresist composition including a complex through an ion exchange reaction. Herein, the cage-type tin oxide cluster and the polymer of Synthesis Example 1 were controlled to have a molar ratio of 50:1 by controlling an input amount of the polymer of Synthesis Example 1. A content of the complex was 1 wt % based on a total amount of the composition.

### Example 2

An inorganic photoresist composition was prepared in the same manner as in Example 1 except that the polymer of Synthesis Example 2 was used instead of the polymer of Synthesis Example 1.

### Example 3

An inorganic photoresist composition was prepared in the same manner as in Example 1 except that the polymer of Synthesis Example 3 was used instead of the polymer of Synthesis Example 1.

### Example 4

An inorganic photoresist composition was prepared in the same manner as in Example 1 except that the polymer of Synthesis Example 4 was used instead of the polymer of Synthesis Example 1.

### Example 5

An inorganic photoresist composition was prepared in the same manner as in Example 1 except that the polymer of Synthesis Example 5 was used instead of the polymer of Synthesis Example 1.

### Example 6

An inorganic photoresist composition was prepared in the same manner as in Example 1 except that the polymer of Synthesis Example 6 was used instead of the polymer of Synthesis Example 1.

### Example 7

An inorganic photoresist composition was prepared in the same manner as in Example 1 except that the polymer of Synthesis Example 7 was used instead of the polymer of Synthesis Example 1.

### Example 8

An inorganic photoresist composition was prepared in the same manner as in Example 1 except that the polymer of Synthesis Example 8 was used instead of the polymer of Synthesis Example 1.

### Example 9

An inorganic photoresist composition was prepared in the same manner as in Example 1 except that the polymer of Synthesis Example 9 was used instead of the polymer of Synthesis Example 1.

### Example 10

An inorganic photoresist composition was prepared in the same manner as in Example 1 except that the polymer of Synthesis Example 10 was used instead of the polymer of Synthesis Example 1.

### Example 11

An inorganic photoresist composition was prepared in the same manner as in Example 1 except that the polymer of Synthesis Example 11 was used instead of the polymer of Synthesis Example 1.

### Example 12

An inorganic photoresist composition was prepared in the same manner as in Example 1 except that the polymer of Synthesis Example 12 was used instead of the polymer of Synthesis Example 1.

### Comparative Example 1

An inorganic photoresist composition including the cationic cage-type tin oxide cluster used in Example 1 (using propylene glycol methyl ether acetate (PGMEA) as a solvent) was used as Comparative Example 1. The composition of Comparative Example 1 included no polymer.

### Comparative Example 2

An inorganic photoresist composition was prepared in the same manner as in Example 1 except that the polymer of Comparative Synthesis Example 1 was used instead of the polymer of Synthesis Example 1.

### Comparative Example 3

An inorganic photoresist composition was prepared in the same manner as in Example 1 except that the polymer of Comparative Synthesis Example 2 was used instead of the polymer of Synthesis Example 1.

### Comparative Example 4

An inorganic photoresist composition was prepared in the same manner as in Example 1 except that the polymer of Comparative Synthesis Example 3 was used instead of the polymer of Synthesis Example 1.

### Comparative Example 5

An inorganic photoresist composition was prepared in the same manner as in Example 1 except that the polymer of Comparative Synthesis Example 4 was used instead of the polymer of Synthesis Example 1.

### Evaluation 1

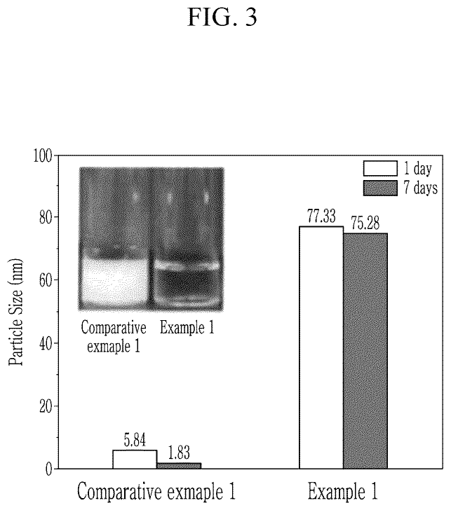

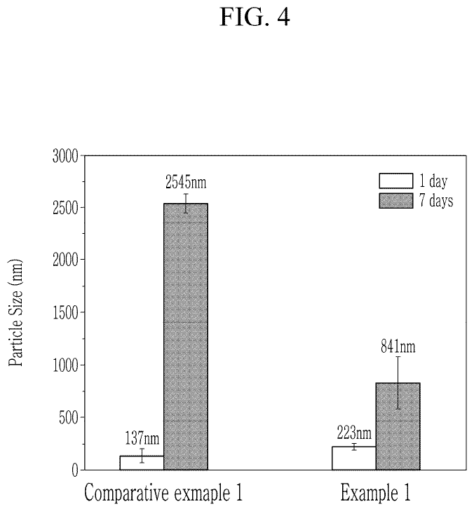

Each of the inorganic photoresist compositions of Examples 1 to 12 and Comparative Examples 1 to 5 was evaluated with respect to a UV transmittance and a particle size, and the results are shown in Tables 1 and 2 and FIGS. 3 and 4. Table 1 shows UV transmittance and particle diameter data measured at the first day after preparing the compositions, and Table 2 shows UV transmittance and particle diameter data measured at the 7^{th} day after preparing the compositions.

TABLE 1

| | Examples | | | | | | | | |
|---|---|---|---|---|---|---|---|---|---|
| | 1 | 2 | 3 | 4 | 5 | 6 | 7 | 8 | 9 |
| Transmittance | 77.33 | 77.62 | 75.78 | 77.58 | 77.67 | 78.11 | 78.10 | 77.02 | 77.03 |
| (%) | | | | | | | | | |
| Particle | 223 | 219 | 227 | 220 | 219 | 216 | 216 | 224 | 224 |
| diameter (nm) | | | | | | | | | |

| | Examples | | | Comparative Example | | | | |
|---|---|---|---|---|---|---|---|---|
| | 10 | 11 | 12 | 1 | 2 | 3 | 4 | 5 |
| Transmittance | 77.34 | 77.36 | 76.99 | 5.84 | 12.16 | 12.24 | 12.20 | 12.25 |
| (%) | | | | | | | | |
| Particle | 223 | 222 | 225 | 137 | 165 | 166 | 164 | 163 |
| diameter (nm) | | | | | | | | |

TABLE 2

| | Examples | | | | | | | | |
|---|---|---|---|---|---|---|---|---|---|
| | 1 | 2 | 3 | 4 | 5 | 6 | 7 | 8 | 9 |
| Transmittance | 75.26 | 76.34 | 74.13 | 75.87 | 76.72 | 77.03 | 77.00 | 75.01 | 75.03 |
| (%) | | | | | | | | | |
| Particle | 841 | 830 | 888 | 835 | 818 | 777 | 773 | 854 | 855 |
| diameter (nm) | | | | | | | | | |

| | Examples | | | Comparative Example | | | | |
|---|---|---|---|---|---|---|---|---|
| | 10 | 11 | 12 | 1 | 2 | 3 | 4 | 5 |
| Transmittance | 75.22 | 75.23 | 74.88 | 1.83 | 2.76 | 2.81 | 2.38 | 2.90 |
| (%) | | | | | | | | |
| Particle | 842 | 842 | 860 | 2545 | 2135 | 1601 | 1504 | 1579 |
| diameter (nm) | | | | | | | | |

As shown in Tables 1 and 2 and FIGS. 3 and 4, structures of the added polymers affected a structure of a complex, and the structure of a complex affected transmittance of the compositions, a particle diameter of the complex, etc. As for inorganic photoresist compositions, because particles (complex, etc.) are boned each other due to agglomeration of the particles within the composition over time, a particle size is increased, ultimately resulting in a decrease in UV transmittance. This is a problem of the inorganic photoresist compositions, and in addition, a structure of the complex is easily deformed over time, which limits a formation of a uniform film during the solution process. Comparatively contrasting Comparative Example 1 with Example 1, Comparative Example 1 exhibited precipitation in a solvent due to strong crystallinity of the cage-type tin oxide nanocluster and thereby, low transmittance and also, an increase in a particle size, when stored for a long time of 7 days or more. On the other hand, Example 1, in which particles of the complex were stably distributed through a strong electrostatic attractive force between anionic polymer and cationic cage-type tin oxide nanocluster, exhibited high transmittance and was suppressed from an increase in a particle size by interactions of the anionic polymer, when stored for a long time of 7 days or more.

### Evaluation 2

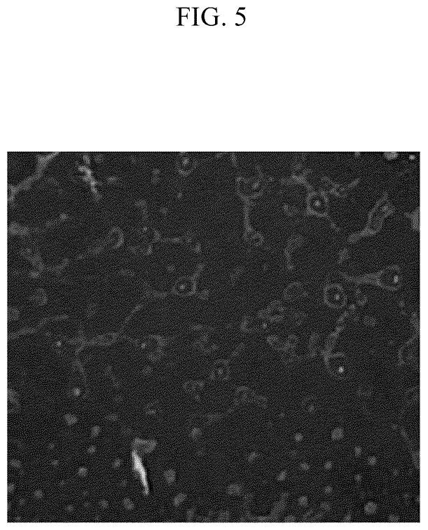

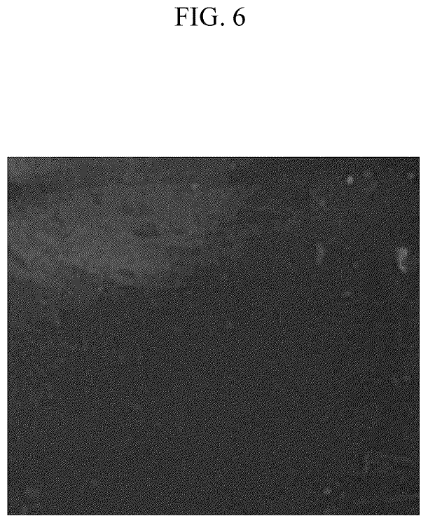

The inorganic photoresist compositions of Example 1 and Comparative Example 1 were allowed to stand for 7 days and then, respectively coated on a silicon wafer to form resist thin films, which were taken an image of with a field emission scanning electron microscope to evaluate properties, and the results are shown in FIGS. 5 and 6. Referring to FIGS. 5 and 6, Comparative Example 1 exhibited generation of lots of defects due to agglomeration of the long-term stored cage-type tin oxide nanocluster, but Example 1 exhibited formation of a very uniform thin film without the agglomeration of cage-type tin oxide nanocluster-anion polymer complex. In other words, the cage-type tin oxide nanocluster, which formed a complex with the anion polymer through high electrostatic bonding, was confirmed to be more stably distributed, and forming a uniform film through high processing characteristics of the polymer.

### Evaluation 3

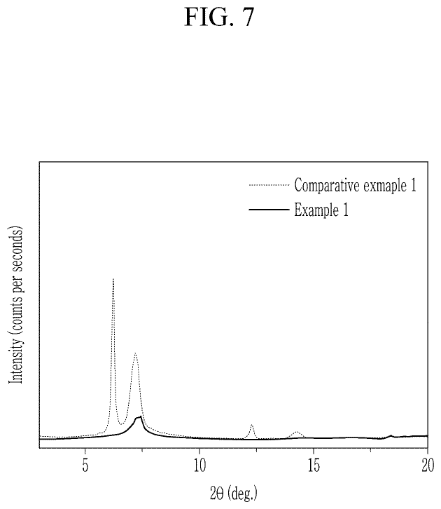

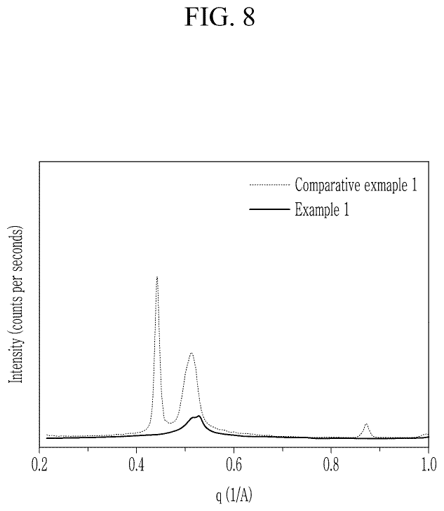

The thin films of Evaluation 2 were evaluated with respect to crystallinity by performing an X-Ray diffraction analysis, and the results are shown in FIGS. 7 and 8. Referring to FIGS. 7 and 8, the thin film formed of the inorganic photoresist composition of Comparative Example 1 exhibited very strong crystalline intensity, but the thin film formed of the inorganic photoresist composition of Example 1 exhibited a very reduced crystalline structure. This can be seen to mean that by adding an anionic polymer to the cage-type tin oxide nanoclusters, the crystallinity of the highly crystalline cage-type tin oxide nanoclusters can be adjusted, leading to higher processability.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A complex comprising
a tin oxide cluster including cations; and
a polymer including an acidic functional group forming an electrostatic attractive force with the tin oxide cluster.

2. The complex of claim 1, wherein
the tin oxide cluster is a cage type.

3. The complex of claim 1, wherein the acidic functional group includes at least one of an anionic functional group or a Lewis acid functional group at a terminal end.

4. The complex of claim 3, wherein
the anionic functional group includes at least one of a sulfurous acid (SO₃⁻), a carbonate (CO₃⁻), a nitric acid (NO₃⁻), a functional group represented by Chemical Formula 1, a functional group represented by Chemical Formula 2, or a combination thereof:

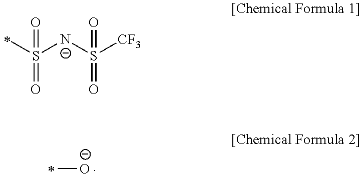

5. The complex of claim 3, wherein
the Lewis acid functional group includes boronic acid.

6. The complex of claim 1, wherein
the polymer further includes, as an additional functional group different from the acidic functional group, at least one of a first additional functional group, a second additional functional group, or a third additional functional group.

7. The complex of claim 6, wherein the first additional functional group includes a functional group derived from an acrylic monomer.

8. The complex of claim 7, wherein the acrylic monomer is a sulfur-free monomer that does not carry an electric charge.

9. The complex of claim 6, wherein the second additional functional group includes a functional group derived from a monomer represented by Chemical Formula 3: 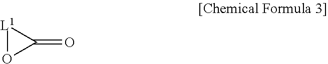
wherein, in Chemical Formula 3,
L¹ is a substituted or unsubstituted C1 to C20 alkylene group.

10. The complex of claim 9, wherein L¹ is a substituted or unsubstituted C3 alkylene group.

11. The complex of claim 6, wherein the third additional functional group includes a functional group derived from a monomer including at least one of a halogen atom or an aromatic monomer.

12. The complex of claim 11, wherein
at least one monomer selected from the monomer including the at least one halogen atom or aromatic monomer is included in an amount of about 5 wt % to about 10 wt % based on a total amount of monomers constituting the polymer.

13. The complex of claim 1, wherein the polymer has a number average molecular weight of less than or equal to about 10,000 g/mol.

14. The complex of claim 1, wherein the tin oxide cluster and the polymer in the complex have a molar ratio of about 50:1.

15. An inorganic photoresist composition, comprising:
a solvent; and
a complex including
a tin oxide cluster including cations, and
a polymer including an acidic functional group having electrostatic attractive force with the tin oxide cluster.

16. The inorganic photoresist composition of claim 15, wherein
the inorganic photoresist composition is a composition configured as an extreme ultraviolet (EUV) light photoresist.

17. The inorganic photoresist composition of claim 15, wherein
the polymer further includes an additional functional group different from the acidic functional group,
the additional functional group includes at least one of a first additional functional group, a second additional functional group, or a third additional functional group,
the first additional functional group includes a functional group derived from an acrylic monomer, and
the second additional functional group includes a functional group derived from a monomer represented by Chemical Formula 3: 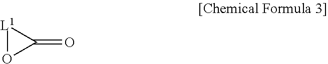
wherein, in Chemical Formula 3 L¹ is a substituted or unsubstituted C1 to C20 alkylene group, and
the third additional functional group includes a functional group derived from a monomer including at least one of a halogen atom or an aromatic monomer.

18. A method of manufacturing a semiconductor device, comprising
coating an inorganic photoresist composition on a substrate;
drying the composition to obtain a film;
exposing the film to light; and
developing the film after exposure,
wherein the inorganic photoresist composition includes
a solvent, and
a complex including
a tin oxide cluster including cations, and
a polymer including an acidic functional group having electrostatic attractive force with the tin oxide cluster.

19. The method of claim 18, wherein the exposing of the film includes exposing the film to extreme ultraviolet (EUV) light.

20. The method of claim 18, wherein
the polymer further includes an additional functional group different from the acidic functional group,
the additional functional group includes at least one selected from a first additional functional group, a second additional functional group, or a third additional functional group,
the first additional functional group includes a functional group derived from an acrylic monomer, and
the second additional functional group includes a functional group derived from a monomer represented by Chemical Formula 3: 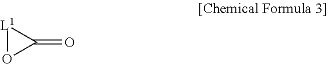
wherein, in Chemical Formula 3, L¹ is a substituted or unsubstituted C1 to C20 alkylene group, and
the third additional functional group includes a functional group derived from a monomer including at least one of a halogen atom or an aromatic monomer.
